(19) United States
(12) Patent Application Publication
(10) Pub. No.: US 2026/0126208 A1
(43) Pub. Date: May 7, 2026

(54) BROADBAND ACCOUSTIC METAMATERIAL

(71) Applicant: AMD Design, LLC, Wilmington, DE (US)

(72) Inventors: Darrin Troy VALLIS, Austin, TX (US); Paul Cameron MERCER, Fairlawn, NJ (US)

(73) Assignee: AMD Design, LLC, Wilmington, DE (US)

(21) Appl. No.: 19/336,883

(22) Filed: Sep. 23, 2025

Related U.S. Application Data
(60) Provisional application No. 63/701,998, filed on Oct. 1, 2024.

(51) Int. Cl. F24F 13/24; H05K 7/20

(52) U.S. Cl. CPC F24F 13/24; H05K 7/20736; F24F 2013/242

(57) ABSTRACT

The broadband acoustic metamaterial disposed within or proximate a server. The broadband acoustic metamaterial includes a body forming a plurality of ducts that have respective open ends configured to be in communication with moving air within or around the server, respective closed ends, respective lengths between the open ends and the closed ends, and respective dimensions (e.g., cross-sections or distances between walls that form the ducts) that are constant throughout the lengths. The ducts are configured to attenuate sound through destructive interference, where the lengths of the ducts correspond to respective target frequencies to attenuate. By using adjacent ducts with different lengths, broadband attenuation may be achieved in a space efficient manner. Furthermore, the ducts may be folded which can provide additional space conserving benefits.

### RELATED APPLICATIONS

This application claims priority to U.S. Provisional Application 63/701,998, filed Oct. 1, 2024, the entire disclosure of which is incorporated herein by reference.

### FIELD

This disclosure is directed to sound reduction in and/or around servers.

### BACKGROUND

Servers often utilize fans to draw air around/through components within the servers to mitigate heat generated by the components. Even in water-cooled servers, fans are used to mitigate heat generated by secondary components within the servers (e.g., components other than processing systems).

Modern servers (e.g., cloud-computing servers, artificial intelligence (AI) and/or machine learning (ML) servers, networking servers, block-chain servers, storage servers, etc.) are performing more tasks than ever before, and, as such, are also generating more heat than ever before. To compensate for the increased heat, air flow requirements have also increased. Increased air flows often means increased noise from the fans and/or from the air moving through the servers.

Further compounding the noise problem is the sheer number of servers that are often collocated. So called “server farms” can contain thousands of servers with compounding noise problems. Noise in such environments is often unwieldy (e.g., require cumbersome hearing protection) and can also negatively affect neighboring rooms (e.g., offices).

All of the subject matter discussed in this section is not necessarily prior art and should not be assumed to be prior art merely as a result of its discussion in this section. Along these lines, any recognition of problems in the prior art discussed in this section or associated with such subject matter should not be treated as prior art unless expressly stated to be prior art. Instead, the discussion of any subject matter in this section should be treated as part of the inventor's approach to the particular problem, which, in and of itself, may also be inventive.

### SUMMARY

Described herein is broadband acoustic metamaterial for a server. The broadband acoustic metamaterial may be an apparatus configured to be disposed within or proximate the server. The broadband acoustic metamaterial includes a body forming a plurality of ducts that have respective open ends configured to be in communication with moving air within or around the server, respective closed ends, respective lengths between the open ends and the closed ends, and respective dimensions (e.g., cross-sections and/or distances between walls that form the ducts) that are constant throughout the lengths. The broadband acoustic metamaterial may be one of many configurations as discussed below in the Detailed Description.

Also described herein is a server containing one or more of the above broadband acoustic metamaterials. The broadband acoustic metamaterials may be configured similarly or different (e.g., have ducts with similar lengths or ducts with different lengths). For example, a first broadband acoustic metamaterial may be disposed in a first area of the server and configured to attenuate sound corresponding to a first set of frequencies, and another broadband acoustic metamaterial may be disposed in a second area of the server and configured to metamaterial sound corresponding to a second set of frequencies. Furthermore, the broadband acoustic metamaterials may have different configurations to accommodate space constraints and/or performance objectives of the respective areas.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

Non-limiting and non-exhaustive embodiments are described with reference to the following drawings, wherein like labels refer to like parts throughout the various views unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings. One or more embodiments are described hereinafter with reference to the accompanying drawings.

FIG. 1 illustrates an example of a server with a plurality of broadband acoustic metamaterials installed therein.

FIG. 2A illustrates an example of a planar broadband acoustic metamaterial.

FIG. 2B illustrates a section view of the planar broadband acoustic metamaterial of FIG. 2A.

FIG. 3 illustrates another example of a planar broadband acoustic metamaterial.

FIG. 4A illustrates an example of a tubular broadband acoustic metamaterial.

FIG. 4B illustrates a section view of the tubular broadband acoustic metamaterial of FIG. 4A.

FIG. 5A illustrates another example of a tubular broadband acoustic metamaterial.

FIG. 5B illustrates a section view of the tubular broadband acoustic metamaterial of FIG. 5A.

FIG. 6 illustrates an example of a hybrid planar/tubular broadband acoustic metamaterial.

FIG. 7A illustrates an example of a folded planar broadband acoustic metamaterial.

FIG. 7B illustrates a section view of the folded planar broadband acoustic metamaterial of FIG. 7A.

FIG. 8A illustrates an example of a folded tubular broadband acoustic metamaterial.

FIG. 8B illustrates a section view of the folded tubular broadband acoustic metamaterial of FIG. 8A.

FIG. 9 illustrates an example implementation of a plurality of planar broadband acoustic metamaterials and a plurality of tubular broadband acoustic metamaterials installed around a plurality of fans.

FIG. 10A illustrates an example implementation of a plurality of folded planar broadband acoustic metamaterials installed around a fan.

FIG. 10B illustrates an example implementation of a plurality of folded planar broadband acoustic metamaterials installed around a plurality of fans.

FIG. 11 illustrates an example configuration of a folded broadband acoustic metamaterial.

FIG. 12 illustrates an example system that may be used to configure a broadband acoustic metamaterial.

### DETAILED DESCRIPTION

### Overview

Modern servers (e.g., cloud-computing servers, artificial intelligence (AI) and/or machine learning (ML) servers, networking servers, block-chain servers, storage servers, etc.) are performing more tasks than ever before, and, as such, are also generating more heat than ever before. To compensate for the increased heat, air flows through such servers have also increased. Even water-cooled servers often require fans to move air through/around components. Such airflows have led to increased noise from the fans and/or from turbulences generated by the airflows. The noise issue is often compounded by large numbers of servers being collocated.

Conventional techniques of noise mitigation (e.g., implementing air ducts, modifying intake and/or exit grills, removing flaps from fans, placing vent holes within chassis of the servers, adding foam or other sound absorption materials, removing finger guards, different blade/fan designs, etc.) are often only marginally effective in reducing sound levels. Furthermore, many conventional techniques come with drawbacks such as decreased server performance, large space consumption, decreased safety, and others.

Described herein is broadband acoustic metamaterial for a server. The broadband acoustic metamaterial may be an apparatus configured to be disposed within or proximate the server. The broadband acoustic metamaterial includes a body forming a plurality of ducts that have respective open ends configured to be in communication with moving air within or around the server, respective closed ends, respective lengths between the open ends and the closed ends, and respective dimensions (e.g., cross-sections and/or distances between walls that form the ducts) that are constant throughout the lengths. The ducts are configured to attenuate sound through destructive interference, where the lengths of the ducts correspond to respective target frequencies to attenuate.

By implementing the ducts, the broadband acoustic metamaterial may be configured to efficiently attenuate multiple target frequencies (e.g., those with highest amplitudes) in a space efficient manner. Doing so may mitigate noise with very little negative impact on server operation. Furthermore, when implemented within many collocated servers, noise levels may be dramatically reduced.

The present disclosure may be understood more readily by reference to this detailed description and the accompanying figures. The terminology used herein is for the purpose of describing specific embodiments only and is not limiting to the claims unless a court or accepted body of competent jurisdiction determines that such terminology is limiting. Unless specifically defined in the present disclosure, the terminology used herein is to be given its traditional meaning as known in the relevant art.

In the following description, certain specific details are set forth in order to provide a thorough understanding of various disclosed embodiments. However, one skilled in the relevant art will recognize that embodiments may be practiced without one or more of these specific details, or with other methods, components, materials, etc. Also in these instances, well-known structures may be omitted or shown and described in reduced detail to avoid unnecessarily obscuring more detailed descriptions of the embodiments.

### Example Server

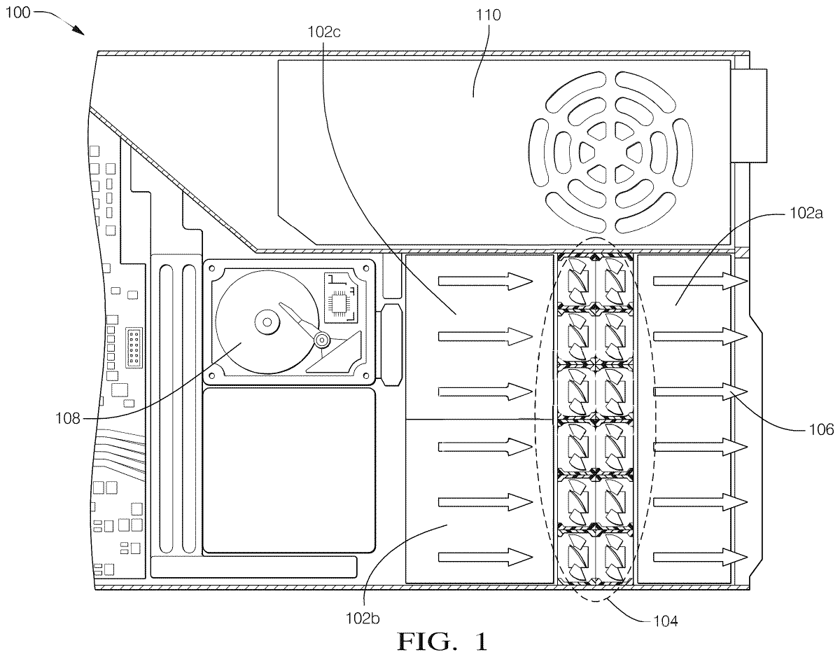

FIG. 1 illustrates an example of server 100 with a plurality of broadband acoustic metamaterials 102 (e.g., broadband acoustic metamaterial 102a, broadband acoustic metamaterial 102b, and broadband acoustic metamaterial 102c) installed therein. The broadband acoustic metamaterials 102 may also be referred to as broadband acoustic attenuators, dampers, dampeners, cancellers, filters, deadeners, mitigators, and the like. Similarly, the broadband acoustic metamaterials 102 may be considered as variable frequency acoustic metamaterials, tightly packed acoustic metamaterials, or spatially-tuned broadband acoustic metamaterials. Broadband, as used herein, refers to a plurality of attenuation frequencies/bands.

Although three of the broadband acoustic metamaterials 102 are shown, the server 100 may include any number of broadband acoustic metamaterials 102 (e.g., more or less than three). Furthermore, the locations of the broadband acoustic metamaterials 102 may vary without departing from the scope of this disclosure. For example, although the broadband acoustic metamaterials 102 are shown within a footprint of the server 100 (e.g., on or near the floor of the server 100), one or more of the broadband acoustic metamaterials 102 may be mounted to a ceiling and/or lid of the server 100 and/or walls of the server 100. The ceiling may be advantageous as there are not many components mounted thereto. Furthermore, one or more of the broadband acoustic metamaterials may be disposed external to the server 100 (e.g., mounted to an outside of a chassis of the server 100, mounted within a hot or cold aisle (e.g., to a door or wall of the hot or cold aisle) proximate the server, to a server rack, etc.).

The broadband acoustic metamaterials 102, individually or in conjunction, may take any of the configurations discussed below and/or be tuned for respective frequencies. In other words, the broadband acoustic metamaterials 102 may be configured for attenuating respective frequency bands, to accommodate packaging requirements, for installation locations within or outside of the server 100, and other factors.

The server 100 includes a plurality of fans 104 configured to create a moving airflow 106 through the server 100. For example, the fans 104 may be configured to draw air from a “cold aisle” or other source, cause the air to flow through/around components within the server 100, and exhaust the air to a “warm aisle” or other sink. Although the airflow 106 is shown as left to right, the airflow 106 may be right to left, up to down, down to up, or any other configuration. The fans 104 may be in any configuration (e.g., differently sized, dispersed, adjacent to one another, facing other directions than shown, etc.) and in any number (e.g., a single fan 104 or more or less fans 104 than illustrated). Regardless of configuration of the server, the airflow 106 moves through the server 100.

Noise may be generated by the fans 104 themselves (e.g., blades of the fans 104) and/or from the airflow 106 moving through the server 100 (e.g., in and around components). Furthermore, noise may be generated by air entering or exiting the server 100. It should also be noted that the broadband acoustic metamaterials 102 may effectively attenuate sound even if the airflow 106 does not exist. For example, the broadband acoustic metamaterials 102 may cancel sound waves from adjacent areas (e.g., other servers) even if the fans 104 are not operating and/or if there is no air moving through the server 100. In general, however, the broadband acoustic metamaterials 102 may be proximate sources of the noise they are configured to attenuate.

The broadband acoustic metamaterials 102 may be configured to attenuate various frequencies depending upon location, target frequencies, neighboring components, etc. For example, broadband acoustic metamaterial 102a may be disposed proximate outlets (e.g., exhaust side) of the fans 104 (e.g., in an outlet flow area) and be configured to attenuate frequencies associated with an exhaust side of the fans 104. The broadband acoustic metamaterial 102a may be tuned to attenuate any number of frequencies (e.g., via respective ducts) associated with the exhaust side noise. In other words, the broadband acoustic metamaterials 102 may include respective bodies forming respective pluralities of ducts. For example, the broadband acoustic metamaterial 102a may be tuned to attenuate m number of frequencies/ranges using m number of ducts with respective lengths. Each duct may have a length that corresponds to a certain target frequency. The m number of ducts may be formed by any number of broadband acoustic metamaterials 102 (e.g., more than one).

The broadband acoustic metamaterial 102b may be disposed proximate intakes of the fans 104 (e.g., within an intake flow area) and be configured to attenuate frequencies associated with an intake side of the fans 104. The broadband acoustic metamaterial 102b may be tuned to attenuate any number of frequencies (e.g., via respective ducts) associated with the intake side noise. For example, the broadband acoustic metamaterial 102b may be tuned to attenuate n number of frequencies/ranges using n number of ducts with respective lengths. Each duct may have a length that corresponds to a certain target frequency. The n number of ducts may be formed by any number of broadband acoustic metamaterials 102 (e.g., more than one).

Certain frequencies of noise may cause a component 108 (e.g., a hard disk drive, memory, etc.) of the server 100 to not perform properly (e.g., cause missed reads and/or writes). Such problems may be caused by vibrations, resonant frequencies, and other issues related to the noise. Accordingly, the broadband acoustic metamaterial 102c may also be disposed proximate intakes of the fans 104, but it may be configured to attenuate frequencies that are problematic for the component 108 (instead of or in addition to frequencies associated with the intake side of the fans 104). It should be noted that even though the airflow is going away from the component 108, sound may travel back to the component 108.

The broadband acoustic metamaterial 102c may be tuned to attenuate any number of frequencies (e.g., via respective ducts) associated with the component 108 and/or intake side fan noise. For example, the broadband acoustic metamaterial 102c may be tuned to attenuate o number of frequencies/ranges using o number of ducts with respective lengths. Each duct may have a length that corresponds to a certain target frequency. The o number of ducts may be formed by any number of broadband acoustic metamaterials 102 (e.g., more than one).

It should be noted that broadband acoustic metamaterials 102 may be combined or divided into any number of structures to make any number of ducts. For example, broadband acoustic metamaterials 102b and 102c may be formed by a single structure (with one or more ducts configured to attenuate noise associated with the component 108 and one or more other ducts configured to attenuate noise associated with the intake side of the fans 104). Furthermore, the broadband acoustic metamaterials 102a, 102b, and 102c may all be formed by a single component with the fans 104 placed thereon.

Broadband acoustic metamaterials 102 may be placed anywhere within and/or around the server 100 and be tuned for any frequencies. As another example, certain frequencies may affect operations of random-access memory (RAM) or other memory systems and, thus, a broadband acoustic metamaterial 102 may be placed proximate a RAM or memory module and tuned to attenuate those detrimental frequencies. As yet another example, a power supply unit (PSU) 110 may generate noise. Accordingly, a broadband acoustic metamaterial 102 may be placed proximate or even within the PSU 110 to attenuate frequencies associated with the PSU 110. As a further example, a broadband acoustic metamaterial 102 may be placed proximate an intake or exhaust grate/port of the server 100 to attenuate frequencies associated with the intake or exhaust grate. It should be noted, however, that a broadband acoustic metamaterial 102 may not be proximate a noise source. In other words, a broadband acoustic metamaterial 102 may be placed remote to a source of noise it is configured to attenuate.

### Example Broadband Acoustic Metamaterials

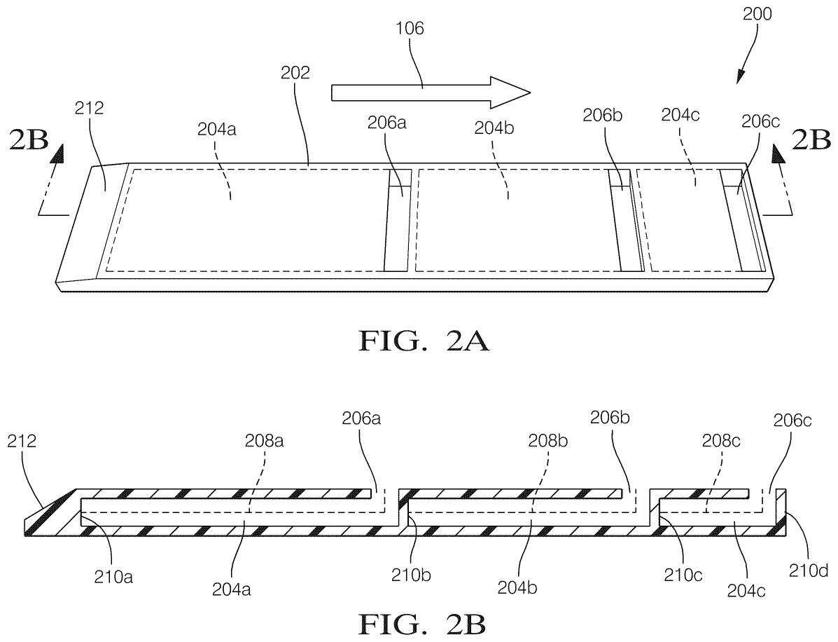

Referring to FIGS. 2A-8B, several example broadband acoustic metamaterials, which are examples of the broadband acoustic metamaterial 102, are described. Not all of the following components are labeled in each of FIGS. 2A-8B. Each of the broadband acoustic metamaterials includes a body 202 that forms a plurality of ducts 204. The ducts 204 are configured to attenuate frequencies that correspond to their respective lengths 208. Accordingly, each broadband acoustic metamaterial 102 includes multiple 1/4 wave ducts which form a broadband acoustic attenuator. The ducts 204 (e.g., 1/4 wave ducts) are spatially compressed and interleaved, thereby realizing a small form factor.

The body 202 may be formed as a single structure or as multiple pieces that are connected or otherwise placed adjacent to each other to form the ducts 204. The body 202 may be formed of metal, plastic, or any other suitable material and may be 3D printed, injection molded (as one or more components), cast, or produced via any other suitable manufacturing processes.

The ducts 204 are formed as caverns or cavities (e.g., closed on most sides) and with respective open ends 206 that, when implemented, may be in contact with an airflow 106. It should be noted that the open ends 206 need not be in direct contact with the airflow 106 to enable the broadband acoustic metamaterials to function. Although better noise mitigation may be achieved when the open ends 206 are proximate the airflow 106, because sound carries through air, the broadband acoustic metamaterials may function with the open ends 206 disposed anywhere where noise is present. Furthermore, although better noise mitigation may be achieved when the airflow 106 flows across the open ends 206 (e.g., along a shorter dimension in most examples), noise mitigation may still be achieved when the airflow flows across a length of the open ends 206 (e.g., along a longer dimension in most examples), or any other direction relative to the broadband acoustic metamaterials.

The open ends 206 define profiles of the ducts 204 that continue along respective paths. In other words, the ducts 204 have similar dimensions throughout their paths. Thus, if an open end 206 has a separation distance (e.g., between walls that form the open end 206), that separation distance will remain constant throughout the path of the associated duct 204. The ducts 204 may have open ends 206 with similar or different dimensions. For example, two of the ducts 204 may have open ends 206 with different minor and major dimensions (assuming they are rectangular or can be flattened to be generally rectangular). If a duct 204 has an open end 206 with a minor dimension that is wider than another, a portion of the broadband acoustic metamaterial corresponding to the duct 204 may have a greater overall thickness (e.g., to maintain the cross-section) than one or more other portions. Similarly, if a duct 204 has an open end 206 with a major dimension that is wider than another, a portion of the planar broadband acoustic metamaterial 200 corresponding to the duct 204 may have a greater overall width than one or more other portions. Although generally rectangular cross-sections are illustrated, the open ends 206, and thus, the cross-sections of the ducts 204 may have any geometric shape.

The ducts 204 are configured as quarter-wavelength resonators (e.g., quarter-wavelength ducts, ¼ wave ducts, etc.) that create sound waves that are half-wavelengths separated in phase with incoming sound. The half-wavelength phase separation is caused by sound waves traveling to ends of the ducts 204 and back to the open ends 206. The out of phase waves combine with the incoming waves to provide cancellation interference.

The frequencies of sound attenuation for the ducts 204 correspond to respective lengths 208 of the ducts 204 (shown as dotted lines in cross sections). The lengths 208 are defined by distances from the open ends 206 to respective closed ends 210. For example, a duct 204 will attenuate frequencies centered around a frequency with a wavelength four times its length 208. As the ducts 204 have different lengths (at least two of the ducts 204 have lengths 208 that differ), their respective center attenuation frequencies also change. It should be noted that each duct 204 will attenuate a range of frequencies around its respective center frequency (e.g., not just the center frequency), although the strongest attenuation may be of the center frequency corresponding to its length 208. For example, amplitudes of attenuation may form bell-curves or other curves centered on the respective center frequencies.

If a duct 204 is straight (e.g., the duct 204 has no bends), then its length 208 is equal to the distance between centroids of its open end 206 and its closed end 210. In most of the following, however, at least a portion of the ducts 204 have bends. In other words, the open ends 206 are swept along respective paths that have at least one bend to form the ducts 204. As such, the lengths 208 are not direct distances but, rather, distances along respective centroid paths (e.g., lines) of the ducts 204. Thus, the lengths 208 are defined along respective centroid paths of the ducts 204 (e.g., along center lines between respective walls that form the ducts 204). Again, the lengths 208 are illustrated in the respective cross sections as dashed lines.

If the broadband acoustic metamaterial 102 is planar, then there may be side walls on each side of the ducts 204 (e.g., one on each side that follows the lengths 208). In other words, each duct 204 may have a top, bottom, and two sides that are constantly apart from one another along the length of the respective duct 204 (assuming the open end 206 is rectangular). If the broadband acoustic metamaterial 102 is tubular, however, then the ducts may not be formed by side walls, as the ducts are contiguous in width. In other words, each duct 204 may have a top and bottom surface that are constantly apart from one another along the length of the respective duct 204. If the broadband acoustic metamaterial 102 is tubular and is truncated and/or has a separation wall, then the sides may exist (albeit differently). The various shapes/configurations of the ducts should be apparent from the illustrated and below described structures.

Regardless of structure, the lengths 208 of the ducts 204 dictate the respective attenuation frequencies/bands, and volumes of the ducts 204 dictate an amount of attenuation. Thus, making a length 208 shorter will raise an attenuation frequency band. Conversely, making a length 208 longer will lower an attenuation frequency band. Raising a volume of a duct 204 will raise an amount of attenuation, and lowering the volume will lower an amount of attenuation. Volume may be changed by changing various dimensions of the duct 204 (e.g., width, height, inner or outer diameter, etc.). It should be noted that the two aspects are generally independent of one another (although changing a length without changing anything else will also change a volume).

The body 202 may also form a lead in chamfer 212 on a windward side of the broadband acoustic metamaterials. The lead in chamfer 212 may enable a smoother transition of the airflow 106 up and over the ducts 204 (e.g., instead of having to transition over a vertical or perpendicular wall of the body 202). The lead in chamfer 212 may also be rounded (e.g., formed as a fillet) to accomplish a similar result.

Turning specifically to FIGS. 2A and 2B, FIG. 2A illustrates a planar broadband acoustic metamaterial 200, which is an example of the broadband acoustic metamaterial 102. FIG. 2B illustrates a section view of the planar broadband acoustic metamaterial 200 of FIG. 2A.

The planar broadband acoustic metamaterial 200 is generally flat. As there are many planar surfaces in the server 100, the planar broadband acoustic metamaterial 200 may be well adapted to be disposed proximate (e.g., on top of) such surfaces.

The planar broadband acoustic metamaterial 200 has three ducts 204 (e.g., ducts 204a-204c) in a row. In some implementations, however, the ducts 204 may be offset from one another in one or more dimensions.

Each of the ducts 204 has a single bend with respective lengths 208 (e.g., 208a, 208b, and 208c) that differ. The single bend may allow for the planar broadband acoustic metamaterial 200 to have a reduced thickness. Although the ducts 204 of the illustrated example only vary by length 208, as noted above, various other dimensions may change between ducts 204 (assuming the respective cross sections are constant for the ducts 204). Changing dimensions may change external dimensions of the planar broadband acoustic metamaterial 200 (e.g., no longer rectangular in plan view). Doing so may maximize noise mitigation while also maximizing space utilization.

Although not illustrated, the planar broadband acoustic metamaterial 200 may not be flat. For example, there may be a space within or proximate the server 100 that is defined by one or more curves or corners. Accordingly, the planar broadband acoustic metamaterial 200 may be formed by adapting or bending along a direction of the row of ducts (e.g., left-right in the FIGS. 2A and 2B).

The planar broadband acoustic metamaterial 200 may be formed via extrusion or any other suitable process. For example, in at least some cases, the ducts 204 may be formed by extruding material in a direction across the ducts 204, and side plates/caps may be formed or attached thereafter.

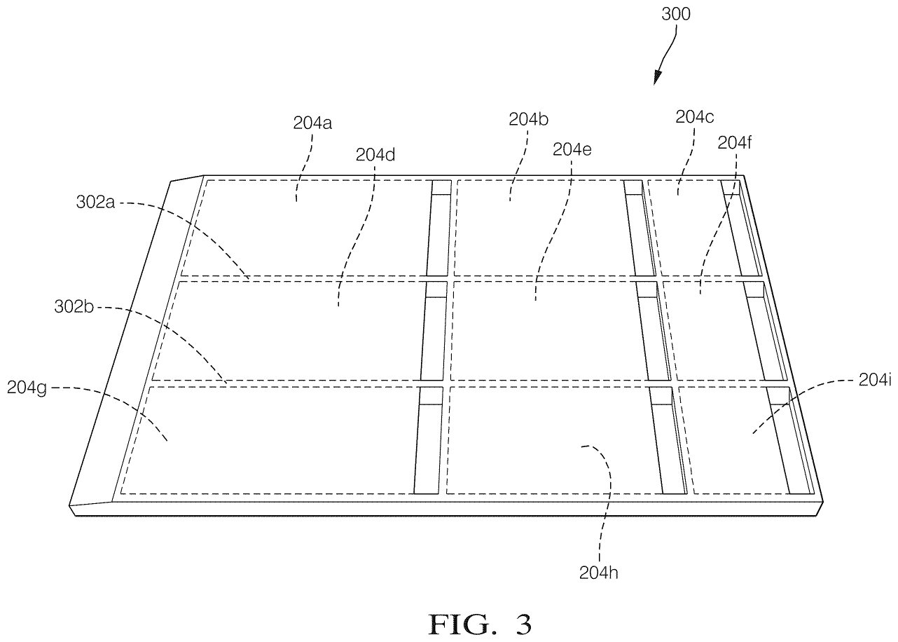

Turning specifically to FIG. 3, FIG. 3 illustrates a planar broadband acoustic metamaterial 300, which is an example of the broadband acoustic metamaterial 102. The planar broadband acoustic metamaterial 300 is similar to the planar broadband acoustic metamaterial 200, except that the planar broadband acoustic metamaterial 300 has multiple rows of ducts 204 (e.g., instead of just a single row of ducts 204).

The planar broadband acoustic metamaterial 300 has nine ducts 204 (e.g., ducts 204a-204i) organized in three rows (e.g., a first row with ducts 204a-204c, a second row with ducts 204d-204f, and a third row with ducts 204g-204i). Any number of rows with any number of respective ducts 204 per row may be used without departing from the scope of this disclosure. Although the planar broadband acoustic metamaterial 300 has similar rows (e.g., each row has the same configuration of ducts 204), the rows may be configured differently (e.g., different length ducts, different width ducts, different number of ducts, etc.).

Between the sets of rows are separation walls 302 (e.g., separation wall 302a and 302b). The separation walls 302 may ease in manufacturing and provide increased rigidity and/or strength. The separation walls 302 may also enable one or more of the ducts 204 to be different lengths from those of adjacent rows. If the rows are configured similarly (e.g., as in the illustrated example), the planar broadband acoustic metamaterial 300 may behave similarly to the planar broadband acoustic metamaterial 200 assuming it had similar external dimensions. For various reasons, however, ducts 204 that are very wide may not be feasible, and, thus, the separation walls 302 may be used.

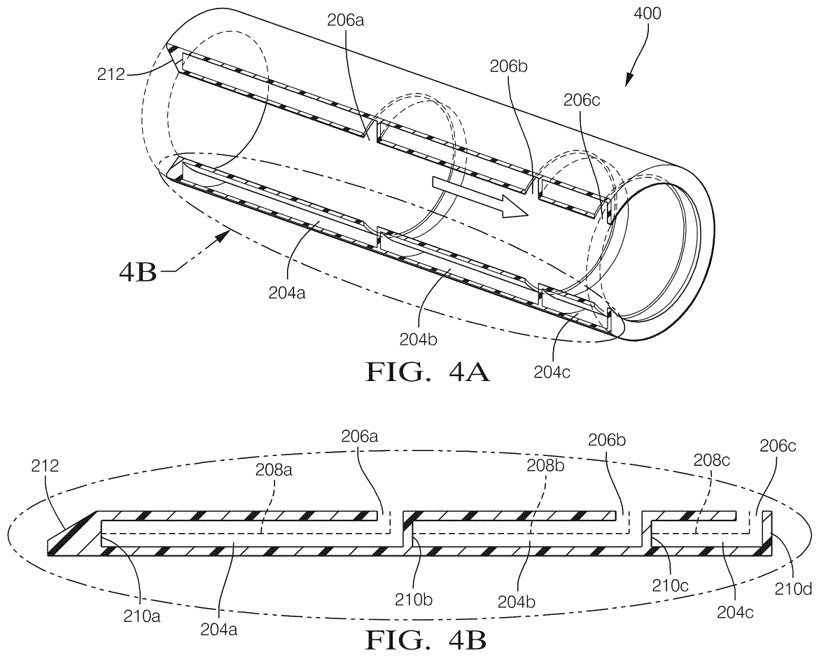

Turning specifically to FIGS. 4A and 4B, FIG. 4A illustrates a tubular broadband acoustic metamaterial 400, which is an example of the broadband acoustic metamaterial 102. FIG. 4B illustrates a section view of the tubular broadband acoustic metamaterial 400 of FIG. 4A.

The tubular broadband acoustic metamaterial 400 is similar to the planar broadband acoustic metamaterial 200, except that the cross section (e.g., profile of the ducts 204) is revolved around an axis to form a cylindrical structure instead of extended along an axis to form a planar structure. In other words, the tubular broadband acoustic metamaterial 400 is formed by a surface of revolution. The tubular broadband acoustic metamaterial 400 may be used in spaces where a planar structure (e.g., planar broadband acoustic metamaterial 200 or planar broadband acoustic metamaterial 300) may be too wide. The tubular broadband acoustic metamaterial 400 may also gain additional attenuation area/volume if space allows (e.g., due to larger relative volumes of the ducts 204). Furthermore, the tubular broadband acoustic metamaterial 400 (or the below tubular broadband acoustic metamaterials) may be used where directing flow is either desired or not disadvantageous.

The tubular broadband acoustic metamaterial 400 may be conceptualized by taking the planar broadband acoustic metamaterial 200 and rolling it (e.g., around an axis parallel to the illustrated flow direction) to form a tube. For simplicity, the tubular broadband acoustic metamaterial 400 has the same cross section as the planar broadband acoustic metamaterial 200. In other words, the lengths 208 and heights of the ducts 204 are the same. The ducts 204 are primarily annular cylindrical caverns instead of square, and the open ends 206 are cylindrical surfaces instead of flat surfaces. To analogize with the planar broadband acoustic metamaterial 200, the widths of the ducts 204 may correspond to an inner or outer circumference of the tubular broadband acoustic metamaterial 400 or any circle therebetween (e.g., a midpoint circle).

In some implementations, there may be one or more separation walls (not shown) within the tubular broadband acoustic metamaterial 400. If separation walls are implemented, the tubular broadband acoustic metamaterial 400 may resemble the planar broadband acoustic metamaterial 300 rolled up to form a tube. For example, if two separation walls are implemented, then two sets of ducts 204 may be formed. If three separation walls 304 are implemented, then three sets of ducts 204 may be formed. Similar to the above, the lengths 208 of the ducts 204 may vary from row to row.

Similar to the planar broadband acoustic metamaterials 200 and 300, the tubular broadband acoustic metamaterial 400 may include the lead in chamfer 212 (albeit now on a round edge instead of a flat edge). The lead in chamfer 212 may enable a smoother transition of the airflow 106 into the interior of the tubular broadband acoustic metamaterial 400.

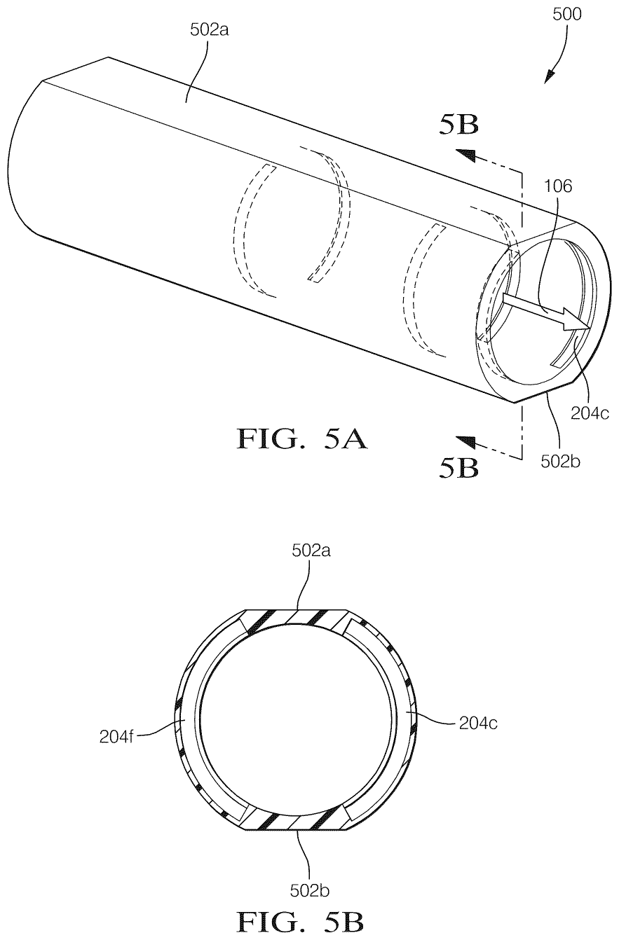

Turning specifically to FIGS. 5A and 5B, FIG. 5A illustrates a truncated tubular broadband acoustic metamaterial 500, which is an example of the broadband acoustic metamaterial 102. FIG. 5B illustrates a section view of the truncated tubular broadband acoustic metamaterial 500 of FIG. 5A. The truncated tubular broadband acoustic metamaterial 500 is similar to the tubular broadband acoustic metamaterial 400, except that the annular cylindrical structure is truncated on two sides to form flat portions 502 (e.g., flat portion 502a and flat portion 502b). The truncated tubular broadband acoustic metamaterial 500 may be used where height restrictions do not enable full revolution of the ducts 204.

For example, the truncated tubular broadband acoustic metamaterial 500 may be used proximate a fan with a height that almost reaches extents of the server 100. A full revolution (e.g., similar to the tubular broadband acoustic metamaterial 400) may cause an inner diameter to shrink to restrict airflow therethrough. The illustrated structure may enable little flow restriction while maximizing a surface area of the ducts 204 (e.g., the open ends 206).

The truncations (e.g., flat portions 502) create two rows of ducts 204 that extend partially around the perimeter of the truncated tubular broadband acoustic metamaterial 500. The flat portions 502 are similar to the separation walls 302 in that they create multiple rows of ducts 204. Because the ducts 204 cannot be revolved around the entire circumference, the ducts 204 are revolved where space between the inner and outer walls of the truncated tubular broadband acoustic metamaterial 500 allows. For example, the ducts 204 may continue through a partial circumferential arc (e.g., 150 degrees of sweep).

FIG. 5B denotes ducts 204c and 204f, as those are the most analogous references from the planar broadband acoustic metamaterial 300). This is because they are the shortest ducts 204 in adjacent rows. The lettering is arbitrary and should not be considered limiting. Furthermore, although the ducts 204 of the respective rows in the illustrated example share the same dimensions, they may be different without departing from the scope of this disclosure. For example, duct 204f may have a longer length than duct 204c.

Although the truncated tubular broadband acoustic metamaterial 500 includes two flat portions 502, there may be more or less than two. More than two flat portions 502 may create more than two rows of ducts 204 while a single flat portion 502 may create a single row of ducts 204. Furthermore, the flat surfaces may or may not be parallel to one another.

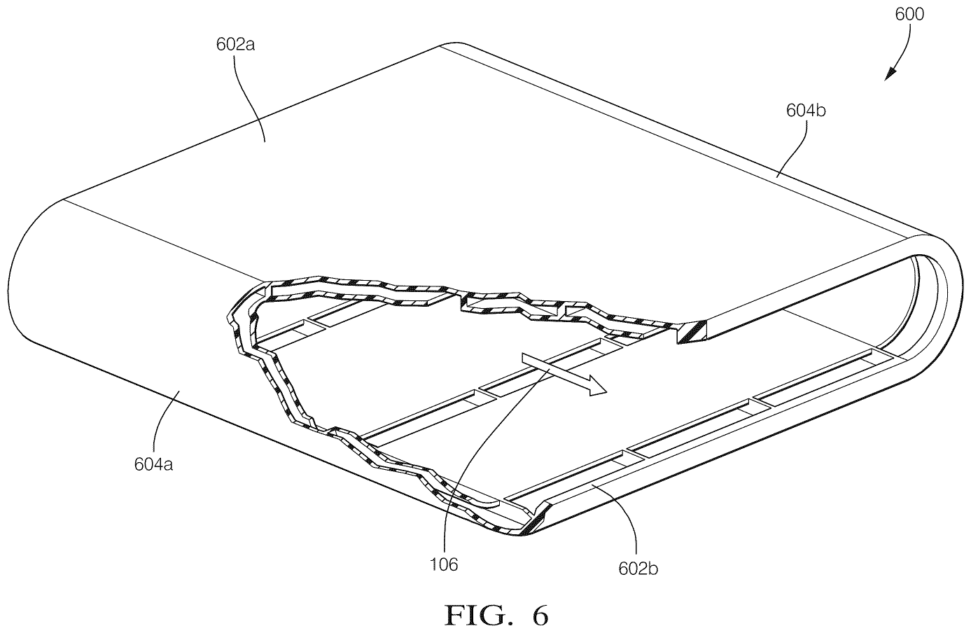

Turning specifically to FIG. 6, FIG. 6 illustrates a hybrid planar/tubular broadband acoustic metamaterial 600, which is an example of the broadband acoustic metamaterial 102. The hybrid planar/tubular broadband acoustic metamaterial 600 incorporates portions that are similar to the broadband acoustic metamaterials discussed above.

The hybrid planar/tubular broadband acoustic metamaterial 600 includes two planar portions 602 (e.g., planar portions 602a and 602b) and two tubular portions 604 (e.g., tubular portions 604a and 604b). The planar portions 602 are similar to the planar broadband acoustic metamaterial 300. As such, they may be configured similarly. Alternatively, the planar portions 602 may be configured similarly to the planar broadband acoustic metamaterial 200 (e.g., a single row of ducts 204). The planar portions 602 may be configured similarly or different from one another (e.g., numbers/configurations of ducts, numbers/configurations of rows, widths of ducts and/or rows, etc.).

The tubular portions 604 are similar to respective portions of the tubular broadband acoustic metamaterial 400. For example, if the tubular broadband acoustic metamaterial 400 were cut in half width-wise, there would be two hemi-cylindrical halves. Each of the tubular portions 604 may be similar to one of the halves.

Between the planar portions 602 and the tubular portions 604 may be separation walls 302. Similar to the above, although not required, the separation walls 302 may enable ease of manufacturing, increased strength and/or rigidity, and/or different lengths of ducts in the respective portions.

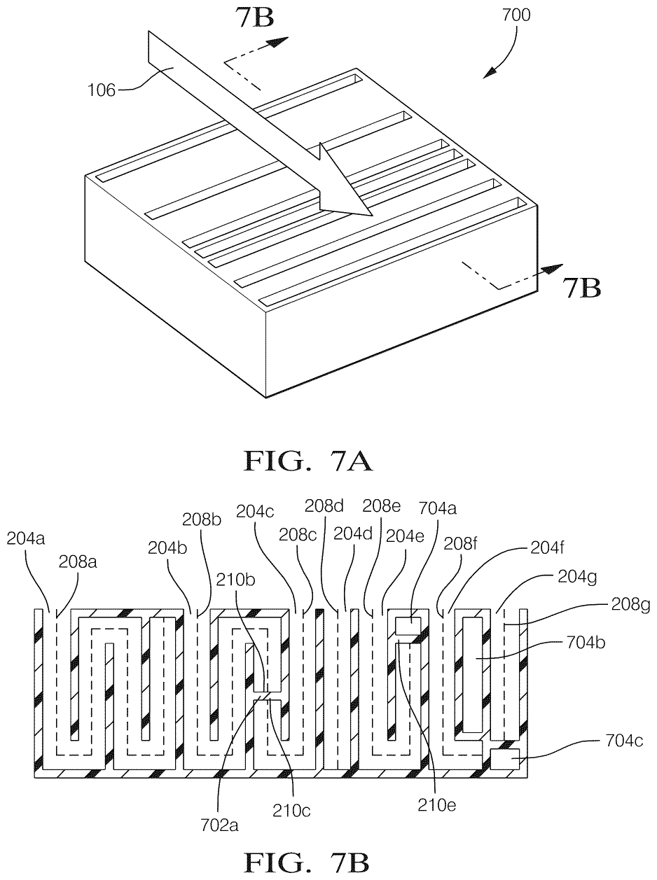

Turning specifically to FIGS. 7A and 7B, FIG. 7A illustrates a folded planar broadband acoustic metamaterial 700, which is an example of the broadband acoustic metamaterial 102. FIG. 7B illustrates a cross section of the folded planar broadband acoustic metamaterial 700 of FIG. 7A. The folded planar broadband acoustic metamaterial 700 is similar to the planar broadband acoustic metamaterial 200, except that some of the ducts 204 have more than one bend and some have no bends (e.g., it is folded where at least one of the ducts 204 has a corner in it).

The previous examples included rows of three ducts (for simplicity). The folded planar broadband acoustic metamaterial 700 includes seven ducts 204 (e.g., ducts 204a-204g). The lengths 208 still correspond to lengths from the open ends 206 to the closed ends 210. By including multiple bends, an overall length of the metamaterial may be reduced (at the expense of height). For example, duct 204a has six bends, which provides for a much reduced left-right footprint than if there was a single bend.

To form the ducts 204, the body 202 may incorporate various structures that have not been discussed above. For example, one or more intermediate walls 702 may be used for form the closed ends 210 of two ducts 204. As illustrated, the intermediate wall 702a creates the closed ends 210b and 210c of ducts 204b and 204c, respectively.

As another example, one or more block structures 704 may be used to take up space between two ducts 204 or between ducts 204 and one or more external surfaces of the folded planar broadband acoustic metamaterial 700. As illustrated, the block structure 704a forms the closed end 210e. Although a wall could be used (e.g., where the bottom of the block structure 704a is), unwanted turbulences may be generated in the cavity that is formed above the wall. In some implementations, the block structures 704 may be solid instead of hollow, as illustrated. The block structures 704 may also be used between two ducts 204 (similar to the intermediate wall 702) depending upon desired lengths. Block structures 704b and 704c illustrate other examples of how to obtain various lengths of the ducts 204 in a compact manner.

The folded planar broadband acoustic metamaterial 700 may be formed via extrusion or another suitable process. For example, in at least some cases, the ducts 204 may be formed by extruding material in a direction across the ducts 204, and side plates/caps may be formed or attached thereafter.

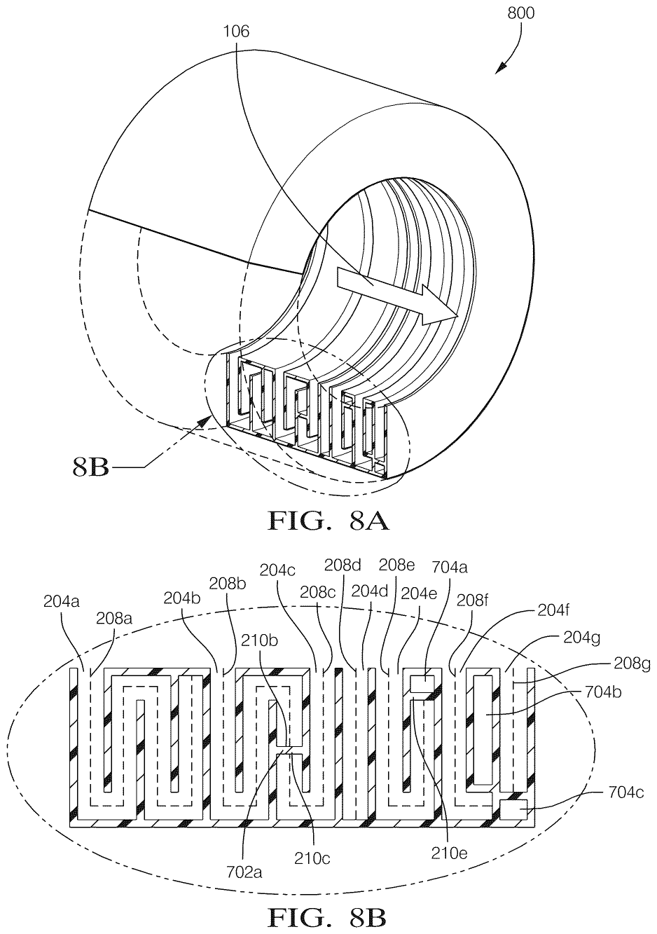

Turning specifically to FIGS. 8A and 8B, FIG. 8A illustrates a folded tubular broadband acoustic metamaterial 800, which is an example of the broadband acoustic metamaterial 102. FIG. 8B illustrates a cross section of the folded tubular broadband acoustic metamaterial 800 of FIG. 8A.

The folded tubular broadband acoustic metamaterial 800 is similar to the folded planar broadband acoustic metamaterial 700, except that the cross section (e.g., profile of the ducts 204) is revolved around an axis to form a cylindrical structure instead of extended along an axis to form a planar structure. In other words, the folded tubular broadband acoustic metamaterial 800 is folded or formed by a surface of revolution with one or more cross sections of ducts that are not straight (e.g., ducts with one or more bends). The folded tubular broadband acoustic metamaterial 800 may be used in spaces where a planar structure (e.g., the planar broadband acoustic metamaterial 200, the planar broadband acoustic metamaterial 300, or the folded planar broadband acoustic metamaterial 700) may be too wide. The folded tubular broadband acoustic metamaterial 800 may also gain additional attenuation area/volume compared to some of the planar structures if space allows (e.g., due to larger relative volumes of the ducts 204). Furthermore, the folded tubular broadband acoustic metamaterial 800 may be used where directing flow is either desired or not disadvantageous.

The folded tubular broadband acoustic metamaterial 800 may be conceptualized by taking the folded planar broadband acoustic metamaterial 700 and rolling it (e.g., around an axis parallel to the illustrated flow direction) to form a tube. For simplicity, the folded tubular broadband acoustic metamaterial 800 has the same cross section as the folded planar broadband acoustic metamaterial 700. In other words, the lengths 208 and heights of the ducts 204 are the same. The ducts 204 are primarily revolved caverns instead of square, and the open ends 206 are cylindrical surfaces instead of flat surfaces. To analogize with the folded planar broadband acoustic metamaterial 700, the widths of the ducts 204 may correspond to an inner or outer circumference of the folded tubular broadband acoustic metamaterial 800 or any circle therebetween (e.g., a midpoint circle).

In some implementations, there may be one or more separation walls (not shown) within the folded tubular broadband acoustic metamaterial 800. For example, if two separation walls are implemented, then two sets of ducts 204 may be formed. If three separation walls 304 are implemented, then three sets of ducts 204 may be formed. Similar to the above, the lengths 208 of the ducts 204 may vary from row to row.

As an example, the folded tubular broadband acoustic metamaterial 800 may have an outer diameter of around 4 inches (e.g., 3.8 inches) and a length of around 4 inches (e.g., 3.7 inches) to easily fit within the confines of the server 100. An inner diameter of the folded tubular broadband acoustic metamaterial 800 may be around 2.5 inches (e.g., 2.44 inches or a wall thickness of 0.68 inches). The folded tubular broadband acoustic metamaterial 800 may have ducts 204 with widths around 0.25 inches wide to allow for good attenuation (e.g., volume) and broadband attenuation (e.g., multiple ducts 204).

Of course, dimensions may vary without departing from the scope of this disclosure. For example, a 4.5 inch outer diameter may be used with a 2.5 inch inner diameter. Given the same overall length and duct lengths as the above example, such a metamaterial may have stronger attenuation due to higher volumes of the ducts 204. Still other dimensions have also been considered by the present inventors are remain in scope of the present disclosure.

Contemplated example dimensions of the folded tubular broadband acoustic metamaterial 800 may be any combination of the following. The width of the ducts 204 may be 1/16 inch, ⅛ inch, ¼ inch, or some other suitable dimension. The wall thickness of the overall shape without material thickness (e.g., a maximum length of a duct 204 without making a turn) may be ½ inch or 1 inch or another suitable dimension. The outer diameter may be 3.5 inches or 4.5 inches, and the length may be 1.25 inches, 2 inches, 3.5 inches, or another suitable dimension.

The example dimensions of the ducts 204 and/or the folded tubular broadband acoustic metamaterial 800 may be applied to other configurations. For example, a broadband acoustic metamaterial 200 that is planar, tubular, hybrid, folded, un-folded, or a combination thereof may assume similar dimensions.

Similar to the tubular broadband acoustic metamaterial 400 and the truncated tubular broadband acoustic metamaterial 500, the folded tubular broadband acoustic metamaterial 800 may include the lead in chamfer 212 as a round edge. The lead in chamfer 212 may enable a smoother transition of the airflow 106 into the interior of the folded tubular broadband acoustic metamaterial 800.

Although not illustrated, in some implementations, the folded tubular broadband acoustic metamaterial 800 may be truncated similar to the truncated tubular broadband acoustic metamaterial 500. In such implementations, the ducts 204 may only revolve partially around the revolution axis. If there is one flat, then the ducts 204 may have sweeps less than 360 degrees. If there are two flats, then two sets of ducts 204 may be formed with sweeps less than 180 degrees.

### Example Implementations

This section describes example implementations of a selection of the broadband acoustic metamaterials 102 discussed above. It should be recognized that the broadband acoustic metamaterials 102 (e.g., the planar broadband acoustic metamaterial 200, the planar broadband acoustic metamaterial 300, the tubular broadband acoustic metamaterial 400, the truncated tubular broadband acoustic metamaterial 500, the hybrid planar/tubular broadband acoustic metamaterial 600, the folded planar broadband acoustic metamaterial 700, or the folded tubular broadband acoustic metamaterial 800, or other variation of the broadband acoustic metamaterial 102) may be used in conjunction with one another depending upon implementation locations, needs, packaging, and other application-specific requirements. Furthermore, as discussed above, any of the broadband acoustic metamaterials 102 may be used alone or in conjunction with others outside of the server 100.

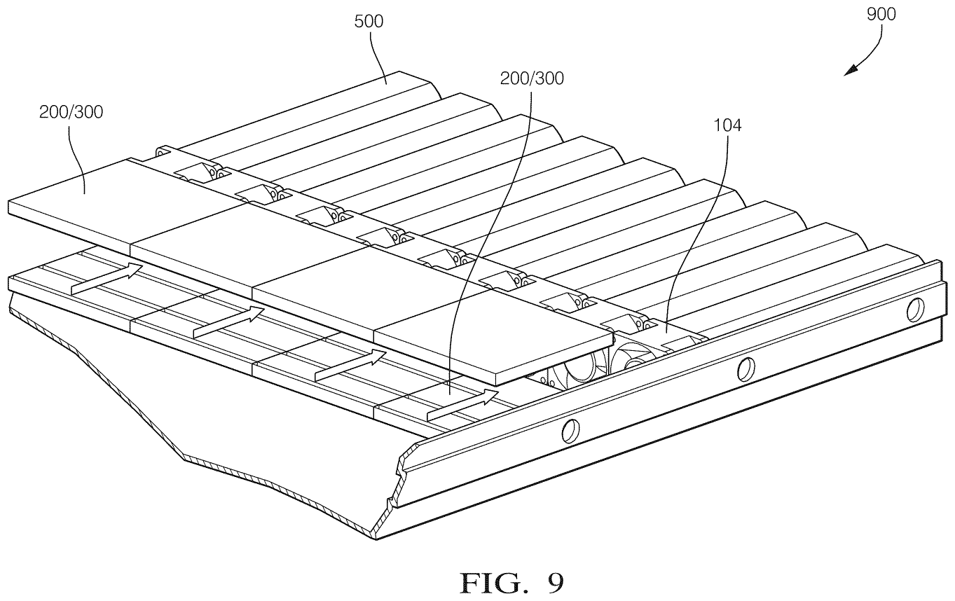

FIG. 9 illustrates an example implementation 900 of a plurality of planar broadband acoustic metamaterials (e.g., planar broadband acoustic metamaterials 200 and/or planar broadband acoustic metamaterials 300) and a plurality of tubular broadband acoustic metamaterials (e.g., truncated tubular broadband acoustic metamaterials 500) installed around a plurality of fans 104. The example implementation 900 may be within the server 100, for example. The illustrated example shows one possible implementation of a plurality of the broadband acoustic metamaterials 102 that are configured differently from one another.

The planar broadband acoustic metamaterials 200/300 are disposed above and below the fans 104 (or near the top and bottom of the fans 104) to form a flat space for the airflow 106 to flow to the fans 104 (e.g., left to right in the illustrated example). The planar broadband acoustic metamaterials 200/300 may each be single metamaterials (e.g., planar broadband acoustic metamaterials 300) or adjacent individual metamaterials (e.g., planar broadband acoustic metamaterials 200). Furthermore, although not shown, they may be single metamaterials that span the fans 104 (e.g., planar broadband acoustic metamaterials 200). As discussed above, however, wide widths without separation walls may be problematic for manufacturing and durability. For simplicity, the rows of ducts 204 are similar; however, one or more of the rows of ducts 204 may be different from other rows of ducts 204.

The truncated tubular broadband acoustic metamaterials 500 may be disposed in a row within an outlet (e.g., effluent) flow of the fans 104. The truncated tubular broadband acoustic metamaterials 500 may be similarly configured (e.g., have ducts 204 with similar lengths 208) or one or more of the truncated tubular broadband acoustic metamaterials 500 may be different from others. Diameters of the truncated tubular broadband acoustic metamaterials 500 may be configured according to sizes of the fans 104.

As discussed above, different portions of the server 100 may require/allow for different attenuation needs and, thus, target frequencies of the broadband acoustic metamaterials 102 disposed in each portion. Furthermore, space and flow requirements may be different in different sections of the server 100. Accordingly, as illustrated, planar broadband acoustic metamaterials 200/300 may work well proximate an intake (e.g., influent side) of the fans 104. At least a portion of the metamaterials may be configured to mitigate frequencies that may affect other components as well. Tubular broadband acoustic metamaterials (e.g., truncated tubular broadband acoustic metamaterial 500) may be well suited for disposition at an effluent side of the fans 104. It should be noted that each server 100 may be configured differently and, thus, may necessitate different configurations of broadband acoustic metamaterials 102. Similarly, implementations out of the server 100 (e.g., within the hot and/or cold aisles) may lead to different configurations of broadband acoustic metamaterials 102.

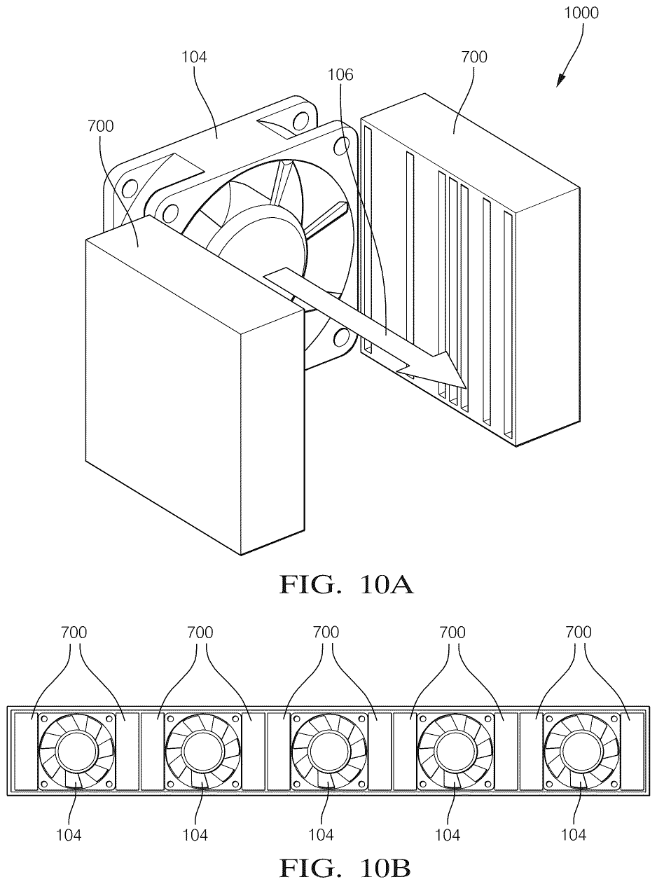

FIG. 10A illustrates an example implementation 1000 of a plurality of folded planar broadband acoustic metamaterials 700 disposed around a fan 104. FIG. 10B illustrates an example implementation 1102 of a plurality of folded planar broadband acoustic metamaterials 700 disposed around/between a plurality of fans 104.

The example implementation 1000 includes two folded planar broadband acoustic metamaterials 700 flanking the fan 104. The folded planar broadband acoustic metamaterials 700 may be on left and right sides of the fan 104 and may have heights that correspond to a diameter of the fan 104, a height of the fan 104, and/or a height of the associated device (e.g., server, aisle, air handling unit). The folded planar broadband acoustic metamaterials 700 may have open ends that face each other and may be disposed on an effluent side (e.g., as shown) or on an intake side of the fan 104.

The folded planar broadband acoustic metamaterials 700 may be disposed perpendicular to a face of the fan 104 (e.g., as shown) or may be disposed at some angle thereto. Furthermore, planar broadband acoustic metamaterials 200/300 may be replace one or more of the folded planar broadband acoustic metamaterials 700 without departing from the scope of this disclosure.

The example implementation 1102 includes five pairs of folded planar broadband acoustic metamaterials 700, with each pair flanking one of the fans 104. In some implementations, the fans 104 can have enough space to enable a pair of back-to-back planar acoustic metamaterials (e.g., the folded planar broadband acoustic metamaterials 700) to be placed between them. For example, they may be spaced apart in a linear array or have large side areas between them. As such, the space between the fans 104 can be well utilized for sound attenuation. As illustrated, a wide area/volume of attenuation can be utilized in a compact space by placing the 10 folded planar broadband acoustic metamaterials 700 between the fans 104. As above, one or more of the folded planar broadband acoustic metamaterials 700 may be replaced with planar broadband acoustic metamaterials 200/300 without departing from the scope of this disclosure.

### Example Configuration

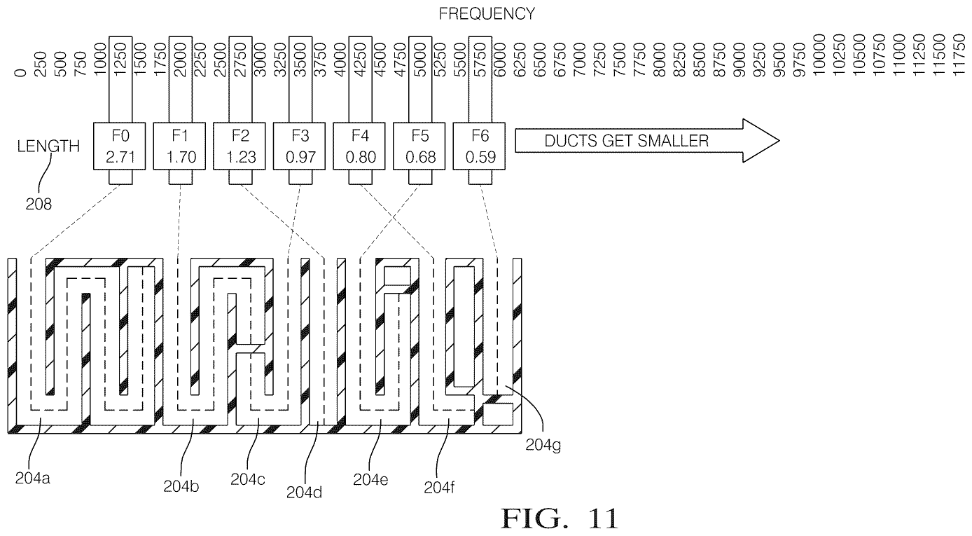

FIG. 11 illustrates an example configuration of a broadband acoustic metamaterial 102. Only a cross section of the broadband acoustic metamaterial 102 is shown, and the cross section, for simplicity, is a similar configuration to those of the folded broadband acoustic metamaterials discussed above. The broadband acoustic metamaterial 102 may be planar or tubular (or a combination thereof) using the illustrated configuration. It should also be recognized that the lengths 208 discussed below may also be used in a non-folded broadband acoustic metamaterial by making the ducts 204 straight (e.g., no bends other than that corresponding to the open ends 206).

The broadband acoustic metamaterial has six ducts 204 (e.g., 204a-204g) with corresponding lengths 208. An attenuation range of frequencies is shown above the cross section with 6 ranges corresponding to the six ducts 204. A series of frequencies are shown ranging from 0 to 6250 Hz in 250 Hz increments. Each of the ducts 204 is configured to attenuate a band of frequencies that spans 500 Hz, centered on respective center frequencies 1104. Each duct 204 has a length 208 (e.g., 208a-208g) that corresponds to its center frequency 1104. It should be recognized that the ducts 204 are not in order of length to minimize a space required for the broadband acoustic metamaterial (e.g., the order minimizes the block structures).

For example, duct 204a is configured to attenuate frequencies between 1000 Hz and 1500 Hz centered on 1250 Hz. To do so, the length of duct 204a is 2.71 inches (4 times a wavelength of sound at 1250 Hz). Duct 204b is configured to attenuate frequencies between 1750 Hz and 2250 Hz centered on 2000 Hz. To do so, the length of duct 204b is 1.70 inches (4 times a wavelength of sound at 2000 Hz). Duct 204c is configured to attenuate frequencies between 2500 Hz and 3000 Hz centered on 2750 Hz. To do so, the length of duct 204c is 1.23 inches (4 times a wavelength of sound at 2750 Hz). Duct 204d is configured to attenuate frequencies between 3250 Hz and 3750 Hz centered on 3500 Hz. To do so, the length of duct 204d is 0.97 inches (4 times a wavelength of sound at 3500 Hz). Duct 204e is configured to attenuate frequencies between 4000 Hz and 4500 Hz centered on 4250 Hz. To do so, the length of duct 204e is 0.80 inches (4 times a wavelength of sound at 4250 Hz). Duct 204f is configured to attenuate frequencies between 4750 Hz and 5250 Hz centered on 5000 Hz. To do so, the length of duct 204f is 0.68 inches (4 times a wavelength of sound at 5000 Hz). Duct 204g is configured to attenuate frequencies between 5500 Hz and 6000 Hz centered on 5750 Hz. To do so, the length of duct 204g is 0.59 inches (4 times a wavelength of sound at 5000 Hz).

The broadband acoustic metamaterial may be tuned to attenuate frequencies ranging anywhere between 0 and 12000 Hz using ducts 204 of corresponding lengths. Furthermore, frequencies and/or frequency bands may be skipped (e.g., have no corresponding ducts 204) and other suitable frequencies and frequency ranges have of course been considered.

### Example Configurator

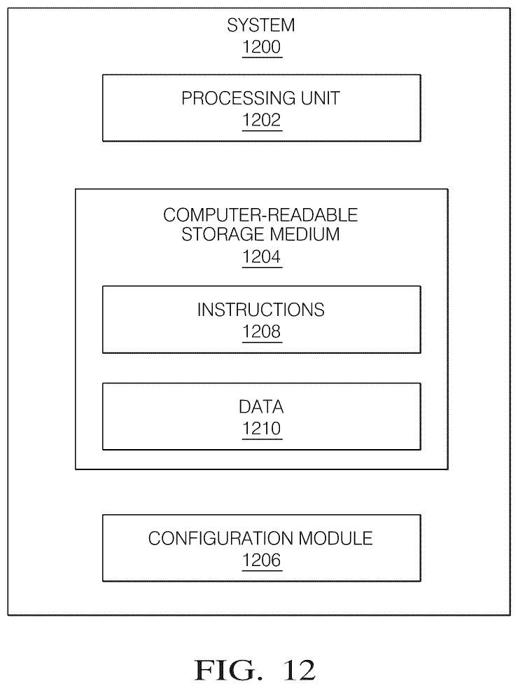

FIG. 12 illustrates an example of a system 1200 that may be used for determining a configuration of a broadband acoustic metamaterial (e.g., any of the examples discussed above). The system 1200 includes at least one processing unit 1202, at least one computer-readable storage medium 1204, and a configuration module 1206.

The processing unit 1202 (e.g., one or more of an application processor, central processing unit (CPU), graphics processing unit (GPU), microprocessor, digital-signal processor (DSP), or controller) executes instructions 1208 (e.g., code) stored within the computer-readable storage medium 1204 (e.g., a non-transitory storage devices such as a hard drive, solid-state drive (SSD), flash memory, random access memory (RAM), read-only memory (ROM), erasable programmable read-only memory (EPROM), or electrically erasable programmable read-only memory (EEPROM)) to cause the system 1200 to determine one or more configurations of a broadband acoustic metamaterial. The instructions 1208 may be part of an operating system and/or one or more applications of the system 1200.

The instructions 1208 cause the processing unit 1202 to act upon (e.g., create, receive, modify, delete, transmit, or display) data 1210 (e.g., application data such as design constraints). Although shown as being within the computer-readable storage medium 1204, portions of the data 1210 may be within a random-access memory (RAM) or a cache of the system 1200 (not shown). Furthermore, the instructions 1208 and/or the data 1210 may be remote to the system 1200.

The configuration module 1206 (or portions thereof) may be comprised by the computer-readable storage medium 1204 or be a stand-alone component (e.g., executed in dedicated hardware in communication with the processing unit 1202 and computer-readable storage medium 1204). For example, the instructions 1208 may cause the processing unit 1202 to implement or otherwise cause the configuration module 1206 to determine the configuration(s) of the broadband acoustic metamaterial.

The system 1200 may also contain a communication system (not shown) that may be any wired or wireless communication system configured to communicate data over one or more connections or networks. For example, the communication system may be configured to communicate data between the system 1200 and a separate device (e.g., a manufacturing device configured to produce the broadband acoustic metamaterial).

Returning to the configuration module 1206, the configuration module 1206 may be configured to receive inputs (e.g., design constraints) corresponding to a configuration of the broadband acoustic metamaterial. The inputs may come from a user of the system 1200 (e.g., via a graphical user interface (GUI)). For example, the configuration module 1206 may receive a plurality of target frequencies (e.g., center frequencies). It should be recognized that each target frequency will have a corresponding duct 204. Thus, if six target frequencies are received, then the broadband acoustic metamaterial will have six ducts 204.

The configuration module 1206 may also receive space constraints. For example, the configuration module 1206 may receive a maximum length, maximum width, maximum height, maximum outer diameter, minimum inner diameter, etc. The space constraints may correspond to a target installation location of the broadband acoustic metamaterial.

The configuration module 1206 may also receive a type of the broadband acoustic metamaterial. For example, the configuration module 1206 may receive an indication that the broadband acoustic metamaterial will be a planar broadband acoustic metamaterial, a tubular broadband acoustic metamaterial, a truncated tubular broadband acoustic metamaterial, a hybrid planar/tubular broadband acoustic metamaterial, a folded planar broadband acoustic metamaterial, or a folded tubular broadband acoustic metamaterial.

The configuration module 1206 may use the target frequencies to determine respective lengths 208 of the ducts 204. From there, the configuration module 1206 may use the other inputs (e.g., space constraints) to determine one or more configurations of the broadband acoustic metamaterial. For example, the configuration module 1206 may produce a plurality of configurations such that a user may select one for implementation.

It should be noted that, if the broadband acoustic metamaterial is a non-folded metamaterial, the order of the ducts 204 may not be significant. In other words, the ducts 204 need not go from shortest to longest or visa-versa for example. If, however, the broadband acoustic metamaterial is a folded metamaterial, then the configuration module 1206 may arrange the ducts 204 according to maximum space utilization. For example, the configuration module 1206 may be configured to arrange the ducts 204 to minimize spaces taken up by the block structures 704.

The configuration module 1206 may also be configured to maximize a total volume (e.g., of all the ducts 204) of the broadband acoustic metamaterial while still adhering to the space constraints. Doing so may enable the broadband acoustic metamaterial to have maximum attenuation in the space provided. The configuration module 1206 may also add separation walls 302 if the broadband acoustic metamaterial is above a certain size (e.g., width, diameter, etc.).

The configuration module 1206 may be configured to output the configuration (e.g., cross section data, outer dimensions, separation wall locations (if any), etc.). The configuration module 1206 may also be configured to output the configuration as a model or other file format such that the broadband acoustic metamaterial can be produced. For example, the configuration module 1206 may output the selected configuration as a file usable by a 3D printer to 3D print the broadband acoustic metamaterial. The configuration module 1206 may also interface with a design software (e.g., computer aided design (CAD), parametric modeler, etc.) to create the model for manufacturing. In such cases, the configuration module 1206 may act as a plug in.

Regardless of how it is implemented, the configuration module 1206 is configured to determine a configuration of a broadband acoustic metamaterial based on a set of inputs. In this way, the configuration module 1206 may enable effective broadband acoustic metamaterials to be designed for many different environments (e.g., frequencies and/or locations) quickly and easily.

### Examples

Example 1: An apparatus configured to be disposed within or proximate a server, the apparatus comprising: a body forming a plurality of ducts, the ducts having: respective open ends configured to be in communication with moving air within or around the server; respective closed ends; respective lengths between the open ends and the closed ends; and respective cross-sections or distances between walls that are constant throughout the lengths.

Example 2: The apparatus of example 1, wherein the ducts are disposed in a row.

Example 3: The apparatus of example 2, wherein the row extends along a direction of the moving air such that the moving air moves across the open ends sequentially.

Example 4: The apparatus of example 3, wherein: the open ends are rectangular; the open ends have a minor dimension direction and a major dimension direction; and the smaller dimension direction is parallel with the direction of the moving air.

Example 5: The apparatus of example 3, wherein the respective lengths are formed by portions of the ducts extending different lengths in the direction of the moving air.

Example 6: The apparatus of example 1, wherein the ducts are disposed in at least two adjacent rows.

Example 7: The apparatus of example 5, wherein the body forms one or more separation walls between the respective adjacent rows.

Example 8: The apparatus of example 1, wherein at least a portion of the respective lengths are formed by portions of the ducts extending different lengths perpendicular to a direction of the moving air.

Example 9: The apparatus of example 1, wherein at least one of the ducts includes at least one 180 degree bend.

Example 10: The apparatus of example 1, wherein the body is formed as an annular cylinder.

Example 11: The apparatus of example 10, wherein an inner diameter of the annular cylinder corresponds to a diameter of a fan of the server.

Example 12: The apparatus of example 10, wherein the open ends are in communication with an interior of the annular cylinder.

Example 13: The apparatus of example 12, wherein the open ends extend around an entire circumference of the interior of the annular cylinder.

Example 14: The apparatus of example 13, wherein the open ends are annular gaps.

Example 15: The apparatus of example 10, wherein the ducts are disposed in a row that extends in an axial direction of the annular cylinder.

Example 16: The apparatus of example 15, wherein the ducts are disposed in at least two radially-adjacent rows.

Example 17: The apparatus of example 16, wherein the body forms one or more separation walls between the respective radially-adjacent rows.

Example 18: The apparatus of example 10, wherein the respective lengths are formed by portions of the ducts extending different lengths along an axial direction of the annular cylinder.

Example 19: The apparatus of example 10, wherein at least a portion of the respective lengths are formed by portions of the ducts extending different radial lengths from the interior of the annular cylinder.

Example 20: The apparatus of example 10, wherein at least one of the ducts includes at least one 180 degree bend.

Example 21: The apparatus of example 1, wherein the body forms a top surface and a bottom surface that are separated by an offset distance.

Example 22: The apparatus of example 21, wherein the body is flat.

Example 23: The apparatus of example 21, wherein the body is curved.

Example 24: The apparatus of example 21, wherein the open ends are coincident with the top surface.

Example 25: The apparatus of example 21, wherein the closed ends are perpendicular to the top surface and the bottom surface.

Example 26: The apparatus of example 21, wherein the closed ends are parallel with the top plane and the bottom plane.

Example 27: The apparatus of example 21, wherein at least one of the ducts is formed by a plurality of surfaces that are parallel to the top surface and the bottom surface.

Example 28: The apparatus of example 1, wherein the body is formed as a truncated annular cylinder with at least one flat external surface that is not an end of the truncated annular cylinder.

Example 29: The apparatus of example 28, wherein the at least one flat external surface includes two flat external surfaces that are 180 degrees offset from one another.

Example 30: The apparatus of example 29, wherein a distance between the two flat external surfaces corresponds to an internal height of the server.

Example 31: The apparatus of example 28, wherein the open ends are in communication with an interior of the truncated annular cylinder.

Example 32: The apparatus of example 31, wherein the ducts comprise two rows of ducts that extend along an axial direction of the truncated annular cylinder.

Example 33: The apparatus of example 32, wherein the ducts extend radially less than 180 degrees.

Example 34: A method comprising: receiving design constraints corresponding to a broadband acoustic metamaterial; determining respective lengths for a plurality of ducts of the broadband acoustic metamaterial based on the design constraints; determining one or more configurations of the broadband acoustic metamaterial based on the design constraints; outputting one of the configurations.

Example 35: The method of example 34, wherein: the design constraints comprise a plurality of target frequencies; and the respective lengths correspond to the target frequencies.

Example 36: The method of example 34, wherein: the design constraints comprise a range of frequencies; the method comprises breaking the range of frequencies into smaller ranges; and the respective lengths correspond to center frequencies of the smaller ranges.

Example 37: The method of any of examples 34-36, wherein the design constraints comprise dimensions of the broadband acoustic metamaterial.

Example 38: The method of any of examples 34-37, wherein the design constraints comprise a type of the broadband acoustic metamaterial.

Example 39: The method of example 38, wherein the type is one of a planar broadband acoustic metamaterial, a tubular broadband acoustic metamaterial, a truncated broadband acoustic metamaterial, a hybrid planar/tubular broadband acoustic metamaterial, a folded planar broadband acoustic metamaterial, or a folded tubular broadband acoustic metamaterial.

Example 40: The method of any of examples 34-39, wherein the method comprises arranging the ducts such that space not corresponding to a duct is minimized.

Example 41: The method of example 40, wherein: the broadband acoustic metamaterial is a folded broadband acoustic metamaterial; and the arranging the ducts comprises arranging the ducts such that block structures within the broadband acoustic metamaterial are minimized.

Example 42: A system comprising a processing unit configured to perform the method of any of examples 34-41.

Example 43: A non-transitory computer-readable storage medium comprising instructions that, when executed by a processing unit, cause the processing unit to perform the method of any of examples 34-41.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

The server may also include a power supply configured to supply power to various components within the server. The power supply may be configured to adapt or change incoming power (e.g., alternating current to direct current and/or stepping up or stepping down voltage). Furthermore, the power supply may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionality of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### Conclusion

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A broadband acoustic metamaterial to be disposed within or proximate a server, the broadband acoustic metamaterial comprising:
a body forming a plurality of ducts, the ducts having:
respective open ends configured to be in communication with moving air within or around the server;
respective closed ends;
respective lengths between the open ends and the closed ends; and
respective dimensions that are constant throughout the lengths.

2. The broadband acoustic metamaterial of claim 1, wherein the broadband acoustic metamaterial is a planar broadband acoustic metamaterial.

3. The broadband acoustic metamaterial of claim 2, wherein the planar broadband acoustic metamaterial is a folded planar broadband acoustic metamaterial.

4. The broadband acoustic metamaterial of claim 1, wherein the broadband acoustic metamaterial is a tubular broadband acoustic metamaterial.

5. The broadband acoustic metamaterial of claim 4, wherein the tubular broadband acoustic metamaterial is a truncated tubular broadband acoustic metamaterial.

6. The broadband acoustic metamaterial of claim 4, wherein the tubular broadband acoustic metamaterial is a folded tubular broadband acoustic metamaterial.

7. The broadband acoustic metamaterial of claim 1, wherein the ducts are disposed in a row.

8. The broadband acoustic metamaterial of claim 7, wherein the row extends along a direction of the moving air such that the moving air moves across the open ends sequentially.

9. The broadband acoustic metamaterial of claim 1, wherein the ducts are disposed in at least two adjacent rows.

10. The broadband acoustic metamaterial of claim 9, wherein the body forms one or more separation walls between the respective adjacent rows.

11. The broadband acoustic metamaterial of claim 1, wherein the lengths are defined along respective centroid paths between respective walls that form the ducts.

12. The broadband acoustic metamaterial of claim 11, wherein at least one of the centroid paths has at least one 90 degree bend.

13. The broadband acoustic metamaterial of claim 11, wherein at least one of the centroid paths has at least one 180 degree bend.

14. A server comprising:
one or more fans configured to generate moving air within the server; and
one or more broadband acoustic metamaterials disposed within a path of the moving air, the broadband acoustic metamaterials comprising:
respective bodies forming respective pluralities of ducts, the ducts having:
respective open ends configured to be in communication with the moving air;
respective closed ends;
respective lengths between the open ends and the closed ends; and
respective dimensions that are constant throughout the lengths.

15. The server of claim 14, wherein at least one of the broadband acoustic metamaterials is disposed within an intake flow area of the path.

16. The server of claim 14, wherein:
the server includes a disk drive; and
at least one of the broadband acoustic metamaterials is configured to attenuate frequencies associated with the disk drive.

17. The server of claim 14, wherein the broadband acoustic metamaterials comprise a first broadband acoustic metamaterial disposed within an intake flow area and a second broadband acoustic metamaterial disposed within an outlet flow area.

18. An aisle proximate to one or more servers, the aisle comprising:
a broadband acoustic metamaterial including:
a body forming a plurality of ducts, the ducts having:
respective open ends configured to be in communication with moving air within the aisle;
respective closed ends;
respective lengths between the open ends and the closed ends; and
respective dimensions that are constant throughout the lengths.

19. The aisle of claim 18, wherein the aisle is a hot or cold aisle.

20. The aisle of claim 18, wherein:
the aisle includes a door; and
the broadband acoustic metamaterial is attached to the door.
